(19) United States
(12) Patent Application Publication
(10) Pub. No.: US 2009/0294906 A1
(43) Pub. Date: Dec. 3, 2009

(54) SEMICONDUCTOR DEVICE AND FABRICATION METHOD FOR THE SAME, AND LIGHT MODULATION DEVICE AND FABRICATION METHOD FOR THE SAME

(75) Inventor: Tatsuya Suzuki, Kyoto-fu (JP)

Correspondence Address: FISH & RICHARDSON P.C., P.O. BOX 1022, MINNEAPOLIS, MN, 55440-1022, US

(73) Assignee: Rohm Co., Ltd., Kyoto-fu (JP)

(21) Appl. No.: 12/473,354

(22) Filed: May 28, 2009

(30) Foreign Application Priority Data
May 29, 2008 (JP) 2006141581

(51) Int. Cl. H01L 29/92; H01L 21/02

(52) U.S. Cl. 257/532; 438/3; 257/295; 257/E29.342; 257/E21.008

(57) ABSTRACT

A light modulation device, which uses the ITO used as a transparent electrode as an etching mask of the PLZT, performing the self-aligned formation, and a fabrication method for the light modulation device is provided. A light modulation device includes a substrate; and a ferroelectric capacitor placed on the substrate and includes a lower electrode, a ferroelectric film placed on the lower electrode, and an upper electrode placed on the ferroelectric film, and the upper electrode includes a conducting film by which self-alignment patterning is performed to the ferroelectric film as an etching mask of the ferroelectric film, and the ferroelectric capacitor is provided so as to laminate on the substrate, and the ferroelectric capacitor is functioned as a Fabry-Perot type resonator from which a refractive index of the ferroelectric film changes according to an electric field applied between the lower electrode and the upper electrode.

### CROSS REFERENCE TO RELATED APPLICATIONS AND INCORPORATION BY REFERENCE

This application is based upon and claims the benefit of priority from prior Japanese Patent Applications No. P2008-141581 filed on May 29, 2008, the entire contents of which are incorporated herein by reference.

### TECHNICAL FIELD

The present invention relates to a semiconductor device and a fabrication method for the semiconductor device, and a light modulation device and a fabrication method for the light modulation device. In particular, the present invention relates to a semiconductor device, which uses a ferroelectric and a fabrication method for the same, and a light modulation device and a fabrication method for the same.

### BACKGROUND ART

In recent years, a digital information recording system using the principle of a hologram is known as a large capacity recording method. As a material of a spatial light modulator of the hologram recording device, a ferroelectric having electro-optical effects, such as Pb(La,Zr,Ti)O₃ (hereinafter PLZT), for example can be used. The PLZT is transparent ceramics which have composition of (Pb_{1-y}La_{y})(Zr₁₋ₓTiₓ)O₃. The electro-optical effect means the phenomenon in which polarization occurs to a substance and a refractive index changes, if an electric field is applied to the substance. If the electro-optical effect is used, the phase of light can be switched by turning ON and turning OFF applied voltage. Therefore, an optical modulation material having the electro-optical effect is applicable to optical shutters, such as a spatial light modulator (for example, refer to Non Patent Literature 1).

In a light modulation device using the PLZT of a thin film formed on a substrate, it is already disclosed also about a fabrication method of a light modulation device, which improves the utilization efficiency of light (for example, refer to Patent Literature 1).

In the fabrication method of the light modulation device according to Patent Literature 1, after using metallic materials, such as Pt, and forming a first reflecting layer on a substrate, a light modulation film using an electro-optics material from which a refractive index changes according to the electric field to apply is formed. Then, a flattening process is performed so that unevenness of the top surface of the light modulation film may become not more than 1/100 of the wavelength of the light which enters into the light modulation device. Then, a transparent electrode using ITO, ZnO, etc. is formed on the light modulation film, and a second reflecting layer composed of a dielectric multilayer is formed. This light modulation device is provided with a Fabry-Perot type resonator with which the light modulation film is formed on the first reflecting layer, and the second reflecting layer is formed on the light modulation film. The reflected light from the resonator is controlled by changing the refractive index by the electric field applied to the light modulation film, and shifting the resonant wavelength of the resonator.

### Citation List

Patent Literature 1: Japanese Patent Application Laying-Open Publication No. 2006-293022
Non Patent Literature 1: Y. Fujimori, T. Fujii, T. Suzuki, et al., “Novel Solid-State Spatial Light Modulator on Integrated Circuits for High-Speed Application with Electro-Optic Thin Film”, the Institute of Electrical and Electronics Engineers (IEEE), Technical Digest of International Electron Devices Meeting(IEDM)), December, 2005, Publishing number 37.7

### SUMMARY OF THE INVENTION

### Technical Problem

The PLZT which is a ferroelectric is known as a difficulty etching substance or material, and when a resist mask is applied, degradation of the etching configuration occurs by going back of resist. At the time of the dry etching technology in such the case, not the resist mask but a hard mask might be used.

In the conventional technology, the selective ratio of the PLZT thick film and the resist mask is wrong, and the resist mask cannot resist the PLZT etching of long duration. Moreover, in the process step using a hard mask, an excessive process step such as a removal process of the hard mask is usually necessary, for example. At the time of etching, the removing method becomes important with a selective ratio (the etching rate of an etching target substance or material and etching of a mask material). Accordingly, in etching of the ferroelectric material, the hard mask which is suitable on the process is not found out conventionally.

The present inventor found out the validity of the ITO as the hard mask which is useful, when etching the PLZT which is the difficulty etching substance or material. That is, the present inventor found out since the ITO becomes fluoride with inactivity if crystallizing, the etching of the PLZT does not need to dare to remove the ITO and according to a self-alignment is possible when using the ITO in that condition as an electrode.

The object of a present invention is to provide a semiconductor device, which uses the ITO used as a transparent electrode as an etching mask of the PLZT, performs the self-aligned formation, and has an easy fabrication method, and a fabrication method for the semiconductor device.

The object of a present invention is to provide a light modulation device, which uses the ITO used as a transparent electrode as an etching mask of the PLZT, performs the self-aligned formation, and has an easy fabrication method, and a fabrication method for the light modulation device.

### Solution to Problem

According to an aspect of the invention, a semiconductor device comprises a ferroelectric capacitor comprising a lower electrode, a ferroelectric film placed on the lower electrode, and an upper electrode placed on the ferroelectric film, wherein the upper electrode includes a conducting film by which self-alignment patterning is performed to the ferroelectric film as an etching mask of the ferroelectric film.

According to another aspect of the invention, a light modulation device comprises a substrate; and a ferroelectric capacitor which is placed on the substrate, and comprises a lower electrode, a ferroelectric film placed on the lower electrode, and an upper electrode placed on the ferroelectric film, wherein the upper electrode includes a conducting film by which self-alignment patterning is performed to the ferroelectric film as an etching mask of the ferroelectric film, and the ferroelectric capacitor is provided so as to laminate on the substrate, and the ferroelectric capacitor is functioned as a Fabry-Perot type resonator from which a refractive index of the ferroelectric film changes according to an electric field applied between the lower electrode and the upper electrode.

According to another aspect of the invention, a fabrication method for a semiconductor device comprises forming a lower electrode; forming a ferroelectric film on the lower electrode: forming an upper electrode including a conducting film on the ferroelectric film; patterning the conducting film; and etching the ferroelectric film and the lower electrode by applying the patterned conducting film as a mask, wherein self-alignment patterning of the conducting film is performed to the ferroelectric film as an etching mask of the ferroelectric film.

According to another aspect of the invention, a fabrication method for a semiconductor device comprises forming a ferroelectric capacitor on a substrate; and forming a control circuit for driving the ferroelectric capacitor on the substrate, and wherein the step of forming the ferroelectric capacitor comprises forming a lower electrode; forming a ferroelectric film on the lower electrode; forming an upper electrode including a conducting film on the ferroelectric film; patterning the conducting film; etching the ferroelectric film and the lower electrode by applying the conducting film as a mask; and forming a dielectric thin film stacked or laminated section on the upper electrode, wherein self-alignment patterning of the conducting film is performed to the ferroelectric film as an etching mask of the ferroelectric film.

### Advantageous Effects of Invention

According to the present invention, the semiconductor device which uses the ITO used as the transparent electrode as the etching mask of the PLZT, performs the self-aligned formation, and has the easy fabrication method, and the fabrication method for the semiconductor device can be provided.

According to the present invention, the light modulation device which uses the ITO used as the transparent electrode as the etching mask of the PLZT, performs the self-aligned formation, and has the easy fabrication method, and the fabrication method for the light modulation device can be provided.

### BRIEF DESCRIPTION OF DRAWINGS

FIG. 1A shows a configuration of a semiconductor device or a light modulation device according to a first embodiment of the present invention, and is a schematic plane pattern configuration diagram.

FIG. 1B shows a configuration of the semiconductor device or the light modulation device according to the first embodiment of the present invention, and is a schematic cross-sectional configuration chart of one pixel part taken in the line I-I of FIG. 1A.

FIG. 2 is a circuit configuration chart of a matrix configuration of the semiconductor device or the light modulation device according to the first embodiment of the present invention.

FIG. 3 is an expansion schematic cross-sectional configuration chart of a resonator 6 of the semiconductor device or the light modulation device according to the first embodiment of the present invention.

FIG. 4 is a schematic cross-sectional configuration chart for explaining one process step of a fabrication method of the semiconductor device or the light modulation device according to the first embodiment of the present invention.

FIG. 5 is a schematic cross-sectional configuration chart for explaining one process step of the fabrication method of the semiconductor device or the light modulation device according to the first embodiment of the present invention.

FIG. 6 is a schematic cross-sectional configuration chart for explaining one process step of the fabrication method of the semiconductor device or the light modulation device according to the first embodiment of the present invention.

FIG. 7 is a schematic cross-sectional configuration chart for explaining one process step of the fabrication method of the semiconductor device or the light modulation device according to the first embodiment of the present invention.

FIG. 8 is a schematic cross-sectional configuration chart for explaining one process step of the fabrication method of the semiconductor device or the light modulation device according to the first embodiment of the present invention.

FIG. 9 is a schematic cross-sectional configuration chart for explaining one process step of the fabrication method of the semiconductor device or the light modulation device according to the first embodiment of the present invention.

FIG. 10 shows a constructional example of the semiconductor device or the light modulation device according to the first embodiment of the present invention, and is an SEM cross section photograph of one pixel part.

FIG. 11 shows an expansion SEM photograph of a part of A of FIG. 10.

FIG. 12A shows a constructional example of the semiconductor device or the light modulation device according to the first embodiment of the present invention, and is an SEM photograph which adopts an ITO hard mask to etch PLZT.

FIG. 12B shows a constructional example of the semiconductor device or the light modulation device according to the first embodiment of the present invention, and is cross sections SEM photograph corresponding to FIG. 12A.

### DESCRIPTION OF EMBODIMENTS

Various embodiments of the present invention will be described with reference to the accompanying drawings. There will be described embodiments of the present invention, with reference to the drawings, where like members or elements are designated by like reference characters to eliminate redundancy, and some layers and their subsidiary regions are designated by the same reference characters for simplicity. Drawings are schematic, not actual, and may be inconsistent in between in scale, ratio, etc.

The embodiments to be described are embodiments of a technical concept or spirit of the present invention that is not limited to embodied specifics, and may be changed without departing from the spirit or scope of claims.

### First Embodiment

### (Semiconductor Device)

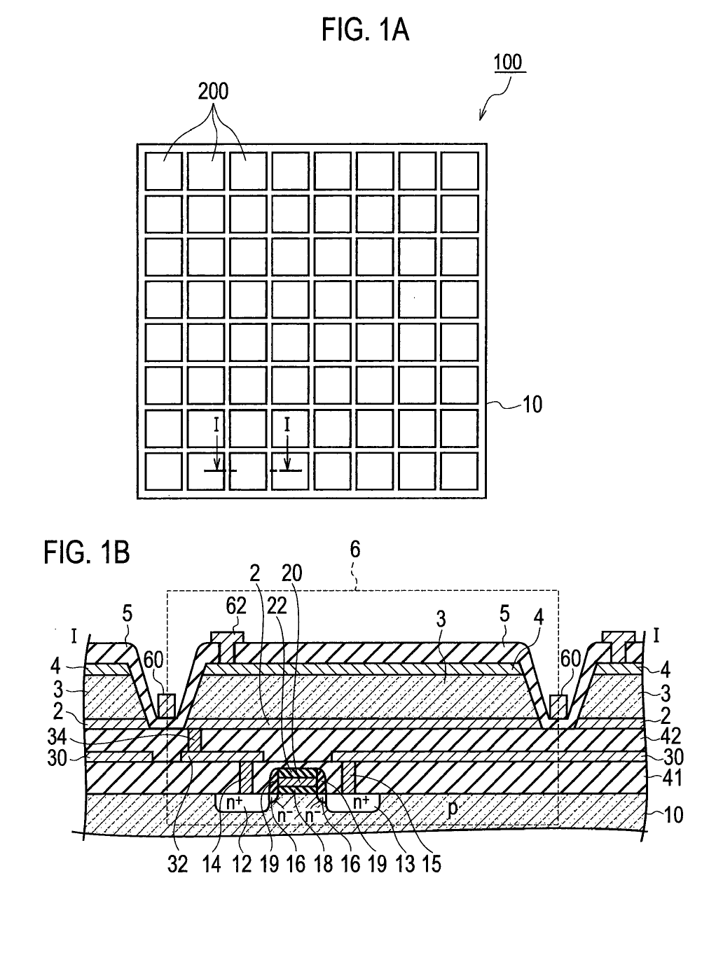

As shown in FIG. 1, a semiconductor device 100 according to a first embodiment of the present invention includes a ferroelectric capacitor including: a lower electrode 2; a ferroelectric film 3 placed on the lower electrode 2; and an upper electrode 4 placed on the ferroelectric film 3. The upper electrode 4 includes the conducting film by which self-alignment patterning is performed to the ferroelectric film 3 as an etching mask of the ferroelectric film 3.

The ferroelectric film 3 includes at least one kind of PLZT, PZT, BST, SBT, LiNbO₃, SBN, TiBaO₃, LSCO, KDP, KTN, a PMN-PT based ceramic film, and a PZN-PT based ceramic film.

Moreover, the conducting film may be formed by ITO of a transparent conductive film.

The lower electrode 2 includes at least one kind of Pt, Ir, iridium oxide, and SRO.

### (Light Modulation Device)

A schematic plane pattern structure of a light modulation device 100 according to the first embodiment of the present invention is expressed as shown in FIG. 1A, and a schematic section structure to which one pixel 200 part is enlarged is expressed as shown in FIG. 1B. FIG. 1 shows an example applied to a reflection type space light modulator for controlling ON/OFF of a reflected light using the ferroelectric capacitor optically. FIG. 1A is a top view of a reflection type light modulation device 100 which places the ferroelectric capacitor to matrix form and on which one ferroelectric capacitor and one switching transistor function as a one pixel 200, respectively.

Although FIG. 1 shows in exemplifying the case where the number of the pixels 200 is 8×8=64 pieces, it is needless to say that the pixel number does not limit to 64 pieces. For example, the reflection type light modulation device etc. which arrays the pixels 200 for 180×180 pieces with a size of 25 μm×25 μm can be formed.

Since the ferroelectric film 3 has an electro-optical effect from which a refractive index changes according to the applied electric field, the light which entered from the upper electrode 4 side is reflected by the reflection type light modulation device 100 shown in FIG. 1 according to the refractive index of the ferroelectric film 3 of each pixel 200. Then, the light by which intensity and a phase are modulated is outputted from the upper electrode 4.

In the reflection type light modulation device 100 shown in FIG. 1, the potential of the upper electrode 4 is common to each pixel 200 connected to the same plate line PL. Therefore, the refractive index of the ferroelectric film 3 of each pixel 200 is controlled by voltage applied to the lower electrode 2. That is, the pixel 200 is independently controllable to a reflection factor by the voltage applied to the lower electrode 2.

The light modulation device 100 according to the first embodiment includes a control circuit 8 for driving the ferroelectric capacitor on a semiconductor substrate, as shown in FIG. 3. Furthermore, the ferroelectric capacitor is provided laminating on the substrate.

In the light modulation device 100 according to the first embodiment, the ferroelectric capacitor is functioned as a Fabry-Perot type resonator from which the refractive index of the ferroelectric film 3 changes according to the electric field applied between the lower electrode 2 and the upper electrode 4.

Moreover, the light modulation device 100 has a dielectric thin film stacked or laminated section on the upper electrode 4. The dielectric thin film stacked or laminated section is formed by a dielectric multilayer 5, for example.

As the light modulation device 100 according to the first embodiment is shown in FIG. 1 in detail, each pixel 200 is placed on a semiconductor substrate 10 at matrix form, and each pixel 200 includes: a VIA electrode 34 formed on the semiconductor substrate 10; the lower electrode 2 connected to the VIA electrode 34; the ferroelectric film 3 placed on the lower electrode 2; the upper electrode 4 placed on the ferroelectric film 3; and the dielectric multilayer 5 placed on the upper electrode 4.

The upper electrode 4 and the ferroelectric film 3 are self-aligned formed.

The material of the ferroelectric film 3 is a material where the polarization state occurred when an electric field is added even after the electric field is no longer applied is held and which changes direction of polarization according to the direction of the electric field from the outside, when forming as a thin film thin enough. In particular, the material which has the hysteresis which is excellent in the rectangularity ratio with large residual polarization and a small coercive electric field can be adopted as the ferroelectric film 3.

Specifically, a Pb(La,Zr,Ti)O₃ (PLZT) film, a Ba(Sr,Ti)O₃ (BST) film, a Pb(Zr,Ti)O₃ (PZT) film, a Ba(Sr,Ti)O₃ (BST) film, a SrBi₂Ta₂O₉ (SBT) film, a strontium niobium barium (SBN) film, a LiNbO₃ film, a TiBaO₃ film, a lanthanum strontium copper oxide (LSCO) film, a KH₂PO₄ (KDP) film, a KTN (potassium tantalum niobium oxide) film, a PMN-PT based ceramic film, and a PZN-PT based ceramic film, etc. are adoptable. Furthermore, the so-called high dielectric is also adoptable.

The upper electrode 4 includes indium tin oxide (ITO) which is a transparent conductive film, and may be a single layer film of the ITO, and is further effective also as a cascade film with transparent electrodes formed in the thin film in which more sufficient transmission rate is obtained, such as platinum (Pt), iridium (Ir), iridium oxide (IrOₓ), a strontium ruthenium oxide (SRO), and zinc oxide (ZnO).

As the lower electrode 2, platinum (Pt), Ir, strontium ruthenium oxide (SRO), etc. are adoptable.

A Fabry-Perot type resonator 6 from which the refractive index of the ferroelectric film 3 changes according to the electric field applied between the lower electrode 2 and the upper electrode 4 is provided.

Silicon (Si), gallium arsenide (GaAs), gallium phosphorus (GaP), galliumnitride (GaN), silicon carbide (SiC), etc. are adoptable as the semiconductor substrate 10, for example. In addition, a sapphire substrate, a silica-based substrate, an SOI (Silicon On Insulator) substrate, etc. are also applicable instead of the semiconductor substrate 10.

On the semiconductor substrate 10, a MOSFET (Metal Oxide Semiconductor Field Effect Transistor) is formed.

The semiconductor substrate 10 is formed by a p-type semiconductor, and an active area by which isolation is performed electrically in the isolation region is formed. As shown in FIG. 1B, the source region or the drain regions (S/D region) 12 and 13 which are formed by n+diffusion region are placed in the active area, and an n- high resistivity region 16 is placed on an n⁺(12, 13)p(10) junction surface where the S/D regions 12 and 13 oppose, an n⁺(12, 13)n⁻(16) p(10) junction is formed, and the reduction and breakdown voltage of leakage current near by the S/D regions 12 and 13 are held.

A gate insulating film 18 is placed on the semiconductor substrate 10 between the S/D regions 12 and 13, a gate electrode 20 is placed on the gate insulating film 18, a cap insulating film 22 is placed on the gate electrode 20, and the sidewall insulating film 19 is further placed at the sidewall part of the gate insulating film 18, the gate electrode 20, and the cap insulating film 22.

On the S/D regions 12 and 13, plug electrodes 14 and 15 are placed, respectively.

The plug electrode 14 is connected to the lower electrode 2 via an M1 electrode 32 and the VIA electrode 34. Moreover, the plug electrode 15 is connected to an M1 electrode 30 connected to bit line BL.

As a result, the resonator 6 composed of the lower electrode 2, the ferroelectric film 3, the upper electrode 4, and the dielectric multilayer 5 is placed on the S/D region 12 of the MOSFET via the plug electrode 14, the M1 electrode 32, and the VIA electrode 34.

An electrode wiring 62 connected to a plate line PL of a ferroelectric memory is placed on the upper electrode 4. Similarly, an electrode wiring 60 connected to a ground line is placed.

Regions 41 and 42 expressed an interlayer insulation film, and have separated each inter-electrode.

In FIG. 1, the interlayer insulation film 42 is placed on the M1 electrode 30 connected to bit line BL, and the lower electrode 2 which functions as M2 electrode is placed on the interlayer insulation film 42. In addition, in this embodiment, although the structure of the two-layer metal of M1 electrode to M2 electrode is shown, it may not limit to this, and it may be 3 to 5 layers metal, for example. The number of layers of the metal should just choose a suitable thing, for example according to a wiring scale. Between such the multilayer electrodes, it is connected via the VIA electrode by metal damascene structure, in predetermined contact section.

In the light modulation device shown in FIG. 1, each lower electrode 2 and the upper electrode 4 which opposes via the ferroelectric film 3 compose one ferroelectric capacitor, respectively, the dielectric multilayer 5 is placed on the upper electrode 4, and the resonator 6 is formed for every pixel 200, as shown in FIG. 1, thereby composing the spatial light modulation device.

In the light modulation device 100 shown in FIG. 1, between the lower electrodes 2 which are spaced out mutually at the same plane and are placed is separated by the dielectric multilayer 5 and the interlayer insulation film 42. The top surface of the ferroelectric film 3 has a tapered shape step. In addition, it is also possible by embedding this tapered shape step with insulating films, such as TEOS (Si(OC₂H₅)₄ Tetraethoxysilane), to maintain surface smoothness to place.

In the reflection type light modulation device 100 shown in FIG. 1, in order to control the reflection factor of the pixel 200, the driver MOSFET, which applies voltage to the lower electrode 2, can be placed under each pixel 200 via the interlayer insulation films 41 and 42, respectively. Therefore, the wiring which connects the driver MOSFET and the pixel 200 can be formed directly under the lower electrode 2 of each pixel 200.

The memory cell transistor composed of the MOSFET is placed, in FIG. 1. The S/D region 13 is connected to the M2 electrode 30 connected to bit line BL, and the S/D region 12 is connected to the plate line via the ferroelectric capacitor. As a result, the ferroelectric memory cell of the one transistor-one capacitor (1T-1C)/cell system is formed.

In the configuration shown in FIG. 1, since the formation of M1 electrode and M2 electrode, etc. via the MOSFET region and each interlayer insulation films 41 and 42 is the same as that of the miniaturization silicon processing, the explanation of the fabrication method is omitted. Since the resonator 6 is a characteristic structure of the light modulation device according to this embodiment, the fabrication method of the detailed part will be described later.

### (Example of Circuit Configuration of Memory Matrix)

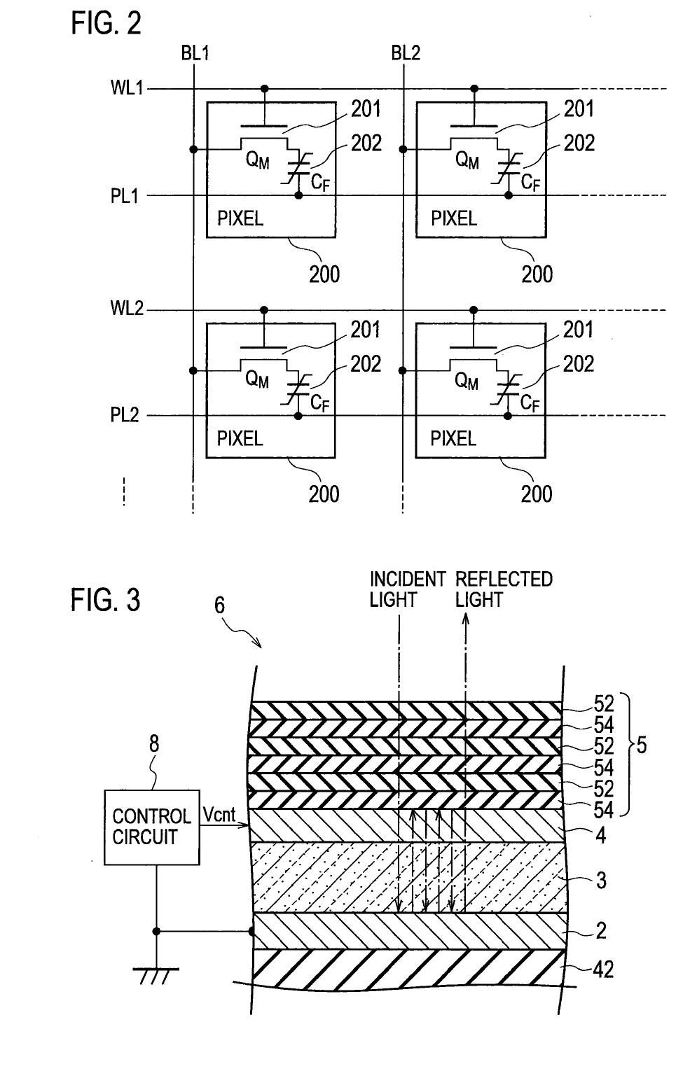

A circuit configuration of a memory matrix configuration of the light modulation device according to the first embodiment is expressed as shown in FIG. 2. Two pixels 200 placed along with one bit line BL of FIG. 2 correspond to the element cross sectional structure of FIG. 1.

The memory matrix configuration of the light modulation device shown in FIG. 2 has multiplebit lines BL1, BL2, . . . arrayed in the row direction, and multiple word lines WL1, WL2, . . . arrayed by the column direction which intersects perpendicularly with this bit lines BL1, BL2, . . . . The pixel 200 controlled by either of the word lines WL1, WL2, . . . or either of the bit lines BL1, BL2, . . . , respectively, is placed at matrix form at a column direction and a row direction.

The pixel 200 is provided with a memory cell transistor (Q_{M}) 201 and a ferroelectric capacitor (C_{F}) 202 which are connected in series, as shown in FIG. 2. Write-in and read-out operation of the pixel 200 are controlled by the memory cell transistor 201. A gate electrode and a drain electrode of the memory cell transistor 201 are connected to the word lines WL1, WL2, . . . and the bit lines BL1, BL2, . . . , respectively, and a source electrode is connected to one side of electrode of the ferroelectric capacitor 202. The electrode of another side of the ferroelectric capacitor 202 is connected to the plate line. For example, the electrode connected to the plate line of the ferroelectric capacitor 202 can be applied as the upper electrode 4 of each pixel 200.

In the pixel 200, data storage holding is performed using the polarization phenomenon of the ferroelectric film 3. That is, since the polarization state of the ferroelectric film 3 is held even if removing an externally applied electric field, even if supply of a power supply stops, the data stored by each pixel 200 does not disappear. Therefore, the pixel 200 operates as a nonvolatile memory.

In addition, although the above-mentioned explanation showed the configuration example of the one transistor-one capacitor (1T-1C) /cell system by which the pixel 200 is composed of the one memory cell transistor 201 and the one ferroelectric capacitor 202, it may be a configuration except this. For example, it may be the case of a configuration example of a two transistor-tow capacitor (2T-2C)/cell system with which the ferroelectric memory cell is composed of the two memory cell transistors Q_{M} and two ferroelectric capacitors C_{F}. Moreover, the configuration example of one transistor (1T)/cell system having the ferroelectric capacitor C_{F} as a gate capacitor of the memory cell transistor Q_{M} may be adopted.

The light modulation device 100 according to the present embodiment is a light modulation device from which the reflection factor changes with the voltage impression from the outside. This light modulation device 100 has the structure of the Fabry-Perot type resonator 6, and includes the ferroelectric film 3 acting as the light modulation film from which the refractive index changes according to impression of the electric field, and a two-layer reflecting layer (the lower electrode 2 and the dielectric multilayer 5) formed as sandwiches the ferroelectric film 3. If the lower electrode 2 which sandwich the ferroelectric film 3 and upper control signal are supplied to the light modulation device 100 in the state where the laser beam is incident, the reflection factor of the light modulation device 100 can be changed, and the intensity of the laser beam reflected can be controlled. Since the laser beam reflected by the light modulation device 100 has the intensity proportional to the reflection factor, it can be used for various applications by recording and detecting this reflected light by recording medium or a photo detector.

### (Configuration of Resonator)

As shown in FIG. 3, the resonator 6 includes: the lower electrode 2 placed on the interlayer insulation film 42; the ferroelectric film 3 placed on the lower electrode; the upper electrode 4 placed on the ferroelectric film 3; and the dielectric multilayer 5 placed on the upper electrode 4.

The resonator 6 includes a ferroelectric capacitor formed by the lower electrode 2, the ferroelectric film 3 placed on the lower electrode 2, and the upper electrode 4 placed on the ferroelectric film 3. Between the lower electrode 2 and the upper electrode 4, the control circuit 8 for driving the ferroelectric capacitor is connected.

The control circuit 8 is formed on the semiconductor substrate 10, for example. The ferroelectric capacitor is placed, laminating on the semiconductor substrate 10.

As a result, the light modulation device functioned as the Fabry-Perot type resonator from which the refractive index of the ferroelectric film 3 changes according to the electric field applied between the lower electrode 2 and the upper electrode 4 is composed.

A switching element is provided on the semiconductor substrate 10, and the resonator 6 is formed on this. Instead of the semiconductor substrate 10, glass with the flat surface, etc. can also be used preferably. Also in this case, it becomes possible to form TFT (Thin Film Transistor) etc. as the switching element.

On the semiconductor substrate 10, the lower electrode 2 acting as a first reflecting layer is formed. The thickness of the lower electrode 2 shall be about 200 nm. In the present embodiment, the lower electrode 2 is formed by Pt, and the lower electrode 2 functions also as an electrode for applying the electric field to the ferroelectric film 3. When the lower electrode 2 is formed by Pt, the reflection factor of the lower electrode 2 is about 50% to about 80%.

The ferroelectric film 3 is provided on the top surface of the lower electrode 2. The thick film t of the ferroelectric film 3 is determined according to the incident angle and the wavelength of incident light, and is formed a range of 500 to 1500 nm preferable when the incident light is applied into the red light near 650 nm, for example. Since the electric field applied to the ferroelectric film 3 is applied to a thickness direction, it becomes easy to apply the electric field for obtaining sufficient refractive index change by a thick film being not more than 1500 nm. Moreover, sufficient optical film thickness variation can be obtained by the thick film being not less than 500 nm.

The upper electrode 4 consisting of a transparent electrode is provided on the top surface of the ferroelectric film 3. When the upper electrode 4 is formed by the ITO, the thickness shall be about 100 nm to about 150 nm. The upper electrode 4 is effective as a single layer film of the ITO which is a transparent conductive film, and it is effective also as a multilayer film by laminating with other conductive materials. For example, when laminating with IrO₂, it is preferable to apply the thick film of the IrO₂ thinner, for example, to be applied as about 50 nm. As for this upper electrode 4, since the value of resistance and the transmission rate become a relation of a trade-off, the thickness may be defined experimentally.

The dielectric multilayer 5 acting as a second reflecting layer is formed on the top surface of the upper electrode 4. As shown in FIG. 3, as for this dielectric multilayer 5, a first dielectric film 52 and a second dielectric film 54 in which the refractive indices n are different are laminated by turns. As a combination of the material of the first dielectric film 52 and the second dielectric film 54, SiO₂ (n=1.46) and Si₃N₄ (n=2.0) can be used. That is, the dielectric multilayer 5 is formed of combination that the refractive index of the first dielectric film 52 is low, and the refractive index of the second dielectric film 54 is high.

Each of the thick films t1 and t2 of the first dielectric film 52 and the second dielectric film 54 is designed so that it may be set to ¼ of the wavelength of the light which is incident into the resonator 6. That is, the thick film t for one layer of each dielectric film is adjusted so that it may become t=λ/(n×4), where λ denotes the wavelength of the light which is incident into the resonator 6, and n denotes the refractive index of the dielectric film.

For example, when a red laser beam with the wavelength of λ=633 nm is used for the light modulation device 100, the thick film t1 of the first dielectric film 52 may be t1=633/(4×1.46)=about 108 nm when applied as SiO₂ (n=1.46) as the material. Moreover, the thick film t2 of the second dielectric film 54 may be t2=633/(4×2)=about 79 nm when Si₃N₄ (n=2.0) is used as the material. The thick films t1 and t2 of the dielectric multilayer 5 composed of the second reflecting layer do not necessarily need to be strictly designed by λ/(n×4). As the material of the dielectric film, TiO₃ (n=2.2) may be used instead of a silicon nitride film. In this case, the thick film t2 of the second dielectric film 54 may be t2=633/(4×2.2)=about 72 nm.

A DBR (Distributed Bragg Reflector) film may be provided as other materials of the dielectric multilayer 5. The DBR film may be formed with the multilayer film including any one of ZrO₂, Al₂O₃, SiO₂, TiO₂, Ta₂O₅, Nb₂O₅, AlN, SiN, AlON, SiON, and AlNₓ (where 0<x<1). In this case, the AlNₓ (where 0<x<1) indicates the case of the composition ratio which shifts from stoichiometry control of AlN. Moreover, the DBR film has high light reflective characteristics, and may be provided with the layered structure which is composed of ZrO₂ film and SiO₂ film, for example. The thickness d1 of ZrO₂ film and the thickness d2 Of SiO₂ film are formed so as to be set to d1=λ/4n₁ and d2=λ/4n₂. In this case, n₁ is the refractive index 2.12 of ZrO₂ film, and n₂ is the refractive index 1.46 of SiO₂ film. For example, d1 is about 48 nm and d2 is about 69 nm for λ=405 nm.

In FIG. 1, it designs so that the reflection factor R2 of the light which is incident into the dielectric multilayer 5 from the ferroelectric film 3 may become equal to the reflection factor R1 of the light which is incident into the lower electrode 2 from the ferroelectric film 3. The reflection factor R1 becomes settled with the metallic material used for the lower electrode 2, and it is 50% to 80% when selecting Pt.

Therefore, at this time, it designs so that the reflection factor R2 may also be 50% to 80%. The reflection factor R2 of the dielectric multilayer 5 can be adjusted by the material and the film thickness of the first dielectric film 52 and the second dielectric film 54. In this embodiment, as shown in FIG. 3, the dielectric multilayer 5 laminates three layers of the first dielectric film 52 and the second dielectric film 54 by turns, respectively. In the dielectric multilayer 5, the order which laminates the first dielectric film 52 and the second dielectric film 54 may be reverse. Moreover, in order to fine-adjust the reflection factor R2, a third dielectric film may be laminated further.

The dielectric multilayer 5 is effective also as a half mirror formed with a metallic thin film.

### (Operation of Resonator)

An operation of the light modulation device 100 composed as mentioned above will be explained.

When the laser beam of the intensity Iin is incident from the upper side of the resonator 6, the part of light which is incident in the Fabry-Perot type resonator 6 is shut up, and the part is reflected. When the intensity of the incident laser beam is set to Iin, and the intensity of the laser beam reflected by the resonator 6 is set to Iout, the reflection factor R of the resonator 6 is defined by R=Iout/Iin.

The reflection factor R of the Fabry-Perot type resonator 6 takes the minimum, in the wavelength λₘ given with the following formula:

λₘ=(2nt cos θ)/m (1)

where m denotes degree, n denotes the refractive index of the ferroelectric film 3, t denotes the thick film of the ferroelectric film 3, and θ denotes the incident angle of the laser beam in the ferroelectric film 3.

As mentioned above, the refractive index n of the ferroelectric film 3 is dependent on the electric field E applied to an electrode pair. At this point, when the control voltage Vcnt outputted from the control circuit 8 between the lower electrode 2 and the upper electrode 4 is applied, the electric field E=Vcnt/t is applied to the ferroelectric film 3 in a thickness direction. When the PLZT is used as the ferroelectric film 3, between amount of variations Δn of the refractive index n of the ferroelectric film 3 and the applied electric field E, the relation of the following formula is satisfied:

Δn=½×(n)³×R×E² (2)

where R denotes the electro-optic constant (Kerr constant).

The resonant wavelength of the resonator 6 is λₘ1 at the time of the reflection property when not applying voltage to the resonator 6. If voltage is applied to the resonator 6, the refractive index of the ferroelectric film 3 changes and the resonant wavelength shifts from λₘ1 to λₘ2. λₘ2 is a larger value than λₘ1.

If the control voltage Vcnt is changed from ground potential to a certain voltage value V1 when the wavelength of the laser beam which is incident into the resonator 6 is set to λₘ1, the reflection factor R of the resonator 61 changes to Rₘ2 from Rₘ1 by shifting the resonant wavelength.

In this case, the ratio Ron/Roff of the reflection factor Roff when not applying voltage, and the reflection factor Ron at the time of applying voltage is defined as an on/off ratio. When the intensity Iin of incident light is fixed, the intensity Iout of the reflected light is proportional to the reflection factor. Therefore, the side where the on/off ratio is larger can control the intensity Iout of the reflected light with sufficient accuracy, and denotes that the utilization efficiency of light is also high.

The reflection factor R of the resonator 6 in the resonant wavelength A becomes so low that the reflection factor R1 in the lower electrode 2 and the reflection factor R2 in the dielectric multilayer 5 are near. Therefore, as mentioned above, by adjusting the number of layers and the material of the dielectric multilayer 5, and designing equally the reflection factor R1 in the lower electrode 2 and the reflection factor R2 in the dielectric multilayer 5, the reflection factor R at the time of off can be set up low, and a high on/off ratio can be taken.

Thus, in the light modulation device 100 according to the present embodiment, by changing the electric field applied to the ferroelectric film 3, the reflection factor can be changed and the optical switch element for controlling the intensity of the reflected light Iout can be achieved.

### (Fabrication Method of Semiconductor Device)

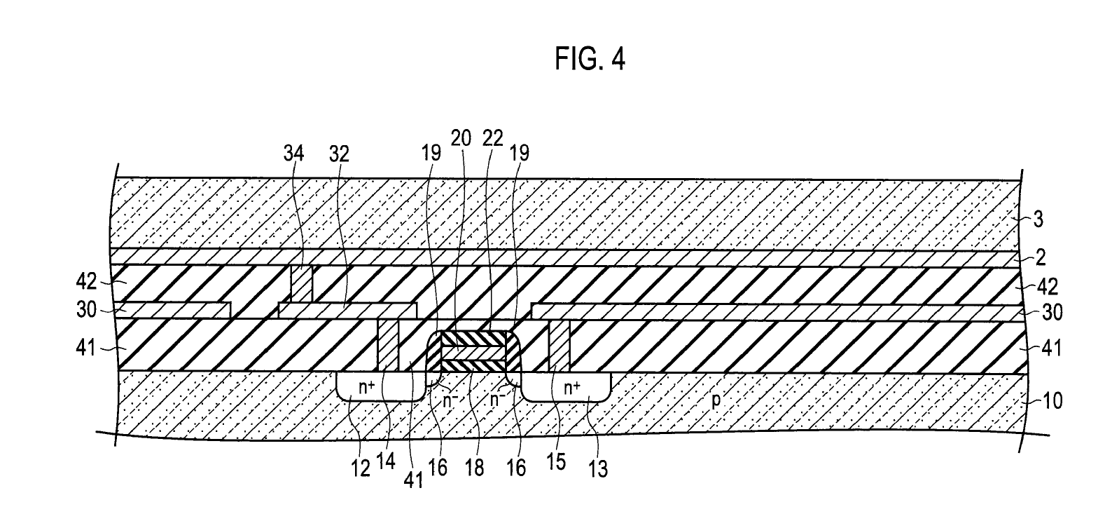

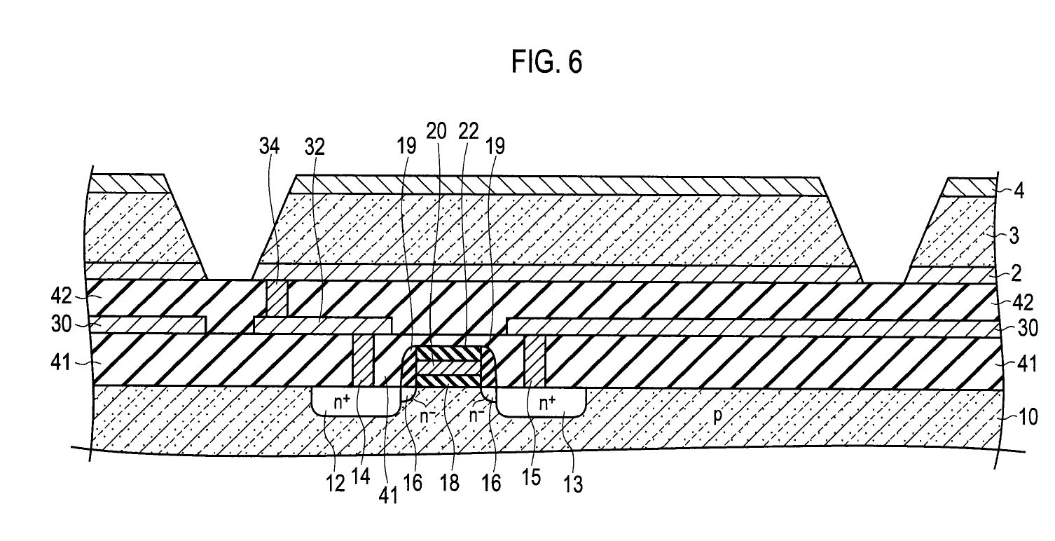

As shown in FIG. 4 to FIG. 8, a fabrication method of the semiconductor device according to the present embodiment includes: the step of forming the lower electrode 2; the step of forming the ferroelectric film 3 on the lower electrode 2; the step of forming the upper electrode 4 including a conducting film on the ferroelectric film 3: the step of patterning the conducting film; and the step of etching the ferroelectric film 3 and the lower electrode 2 by applying the patterned conducting film as a mask. Self-alignment patterning of the conducting film is performed with the ferroelectric film 3 as an etching mask of the ferroelectric film 3.

The step of using the ITO as the conducting film and etching the ferroelectric film 3 and the lower electrode 2 by applying the conducting film as a mask switches gas series of dry etching and is performed.

The step of using the PLZT as the ferroelectric film 3 and etching the ferroelectric film 3 applies C₄F₈ gas, CF₄ gas, or Ar gas as the dry etching gas series.

The step of using Pt as the lower electrode 2 and etching the lower electrode 2 applies C₄F₈ gas, CF₄ gas, Ar gas, or Cl₂ gas as the dry etching gas series.

### (Fabrication Method of Light Modulation Device)

A fabrication method of the light modulation device according to the present embodiment includes the step of forming a ferroelectric capacitor on a substrate, and the step of forming a control circuit for driving the ferroelectric capacitor on the substrate, as shown in FIG. 4 to FIG. 8.

In the fabrication method of the light modulation device according to the present embodiment, the step of forming the ferroelectric capacitor includes: the step of forming the lower electrode 2; the step of forming the ferroelectric film 3 on the lower electrode 2; the step of forming the upper electrode 4 including a conducting film on the ferroelectric film 3; the step of patterning the conducting film; the step of etching the ferroelectric film 3 and the lower electrode 2 by applying the conducting film as a mask; and the step of forming a dielectric thin film stacked or laminated section on the upper electrode 4. The dielectric thin film stacked or laminated section can be formed by the dielectric multilayer 5, for example. Self-alignment patterning of the conducting film is performed with the ferroelectric film 3 as an etching mask of the ferroelectric film 3.

The lower electrode 2 may be formed by at least any one kind of Pt, Ir, iridium oxide, and SRO.

The step of using the ITO as the conducting film and etching the ferroelectric film and the lower electrode by applying the conducting film as a mask switches gas series of dry etching and is performed.

The step of using the PLZT as the ferroelectric film and etching the ferroelectric film applies C₄F₈ gas, CF₄ gas, or Ar gas as a dry etching gas series.

The step of using Pt as the lower electrode and etching the lower electrode 2 applies C₄F₈ gas, CF₄ gas, Ar gas, or Cl₂ gas as the dry etching gas series.

In detail, as shown in FIG. 4 to FIG. 8, the fabrication method of the light modulation device according to the present embodiment includes: the step of forming the lower electrode 2; the step of forming the ferroelectric film 3 on the lower electrode 2; the step of forming the upper electrode 4 on the ferroelectric film 3; the step of patterning the upper electrode 4; the step of etching the ferroelectric film 3 by applying the patterned upper electrode 4 as a mask; and the step of forming the dielectric multilayer 5 on the upper electrode 4.

The upper electrode 4 and the ferroelectric film 3 are self-aligned formed.

The ferroelectric film 3 is formed by any one kind of PLZT, PZT, BST, SBT, LiNbO₃, SBN, TiBaO₃, LSCO, KDP, KTN, a PMN-PT based ceramic film, and a PZN-PT based ceramic film.

The upper electrode 4 includes at least the ITO, and may also be as a multilayer film which includes at least any one kind of Pt, Ir, iridium oxide, ZnO, and SRO.

The lower electrode 2 is formed by any one kind of Pt, Ir, and SRO.

Hereinafter, the fabrication method of the ferroelectric light modulation device according to the present embodiment will be explained in detail using FIG. 4 to FIG. 8.
(a) First of all, as shown in FIG. 4, after forming MOSFET acting as a memory cell transistor on the semiconductor substrate 10, the interlayer insulation film 41 is deposited by the CVD insulating film, a TEOS film, etc., for example, and the plug electrodes 14 and 15 are formed. As a material of the plug electrodes 14 and 15, W etc. are applied with the miniaturization of a memory cell transistor, for example.

Here, the step of forming the plug electrodes 14 and 15 by the W-plug will be explained. After forming a contact hole of a high aspect ratio for the interlayer insulation film 41, WF₆ of material gas is reduced by H₂, SiH₄, etc. when embedding this contact hole by W electrode.

The reaction in the case of H₂ reduction is expressed by WF₆+H₂→W+6HF. Moreover, the reaction in the case of SiH₄ reduction is expressed by 2WF₆+3SiH₄→2W+3SiF₄+6H₂.

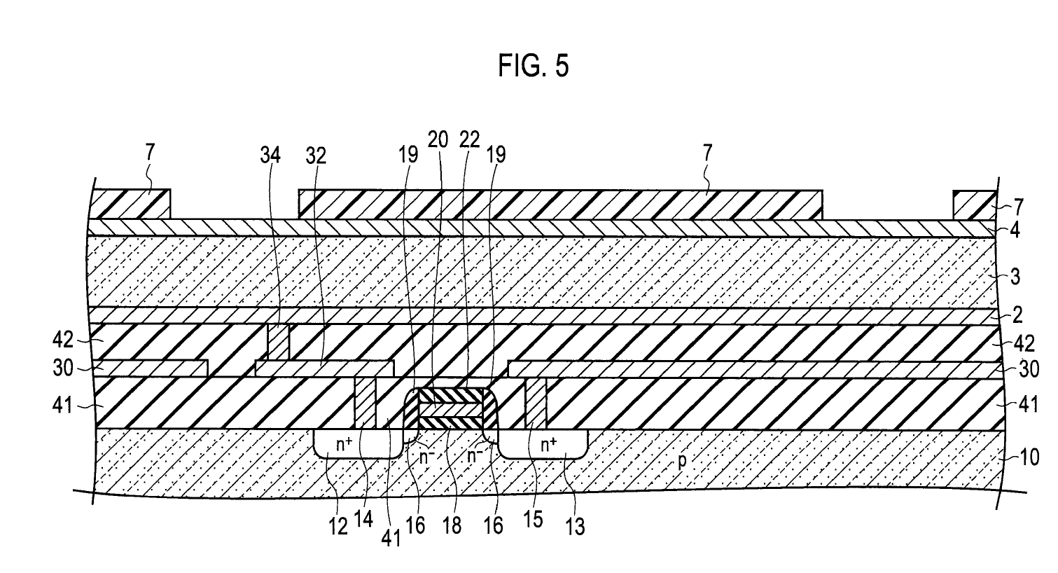

In addition, the usual silicon miniaturization process is applicable to the formation process of the MOSFET. For example, the isolation region is formed of STI (Shallow Trench Isolation) technology. The gate insulating film 18 is formed of a thermal oxidation processing. The S/D region 12, the S/D region 13, and the high resistance region 16 are formed of the ion implantation technology of arsenic or Lynn, or a diffusion processing. The gate electrode 20 is formed of polysilicon formatting technology, for example. In the electrode forming metalization processing over the SID region 12, the S/D region 13, and the gate electrode 20, it is also possible to apply the silicide technology of W, molybdenum (Mo), cobalt (Co), etc. for forming miniaturization electrical contact. For the sidewall insulating film 19 and the cap insulating film 22, the deposition technology, such as a CVD oxide film and a CVD nitride film, is applied. The explanation is omitted about the fabricating process of the MOSFET here.
(B) Next, as shown in FIG. 4, the M1 electrode 32 is formed on the surface of the interlayer insulation film 41 and the plug electrode 14. Similarly, the M1 electrode 30 is formed on the surface of the interlayer insulation film 41 and the plug electrode 15. The M1 electrode 32 is connected to the lower electrode 2 via the VIA electrode 34, and the M1 electrode 30 is connected to the bit line BL. The M1 electrode is formed by using a material (for example, W, TiN, Ti, and these cascade films) which can resist the heat at the time of film formation of the ferroelectric film.
(c) Next, as shown in FIG. 4, the VIA electrode 34 is formed after forming the interlayer insulation film 42 with a CVD insulating film, a TEOS film, etc., for example on the interlayer insulation film 41 and the M1 electrodes 30 and 32. As a material of the VIA electrode 34, W etc. are applied as well as the plug electrodes 14 and 15, for example. As other materials, a layered structure of Cu/polysilicon may be formed in line with the internal wall of a trench. In this case, about the step of forming the VIA electrode 34 by the W-plug, it can form by WCVD by H₂ reduction reaction or SiH₄ reduction reaction, as well as the plug electrodes 14 and 15.
(d) Next, as shown in FIG. 4, the lower electrode 2 is formed on the VIA electrode 34 and the interlayer insulation film 42. The lower electrode 2 is formed by Pt, Ir, SRO, etc. by the sputtering method etc. of a thick film of about several 10 nm to about 100 nm, for example. In detail, the lower electrode 2 may be formed by double layer structure. For example, an IrTa film is formed by the sputtering method, and then an Ir film is similarly formed by the sputtering method on the IrTa film. The thick films of each layer are about several 10 nm to about 100 nm.
(e) Next, as shown in FIG. 4, the ferroelectric film 3 is formed on the lower electrode 2. For example, a PLZT film, PZT, a BST film, an SBT film, an SBN film, an LiNbO₃ film, a TiBaO₃ film, an LSCO film, a KDP film, a KTN film, a PMN-PT based ceramic film, a PZN-PT based ceramic film, etc. are formed with the sputtering method, the MOCVD method, the sol gel process, etc. Specifically, a PLZT film is formed by about 1 μm thick film, for example using the sol gel process etc.
(e) Next, as shown in FIG. 5, the upper electrode 4 is formed on the whole surface of the ferroelectric film 3. As the upper electrode 4, a transparent electrode, such as an ITO film, Pt, Ir, iridium oxide (IrO_{y}), an SRO film, or a ZnO film, is formed by the sputtering method etc. by about 200 nm thick film.

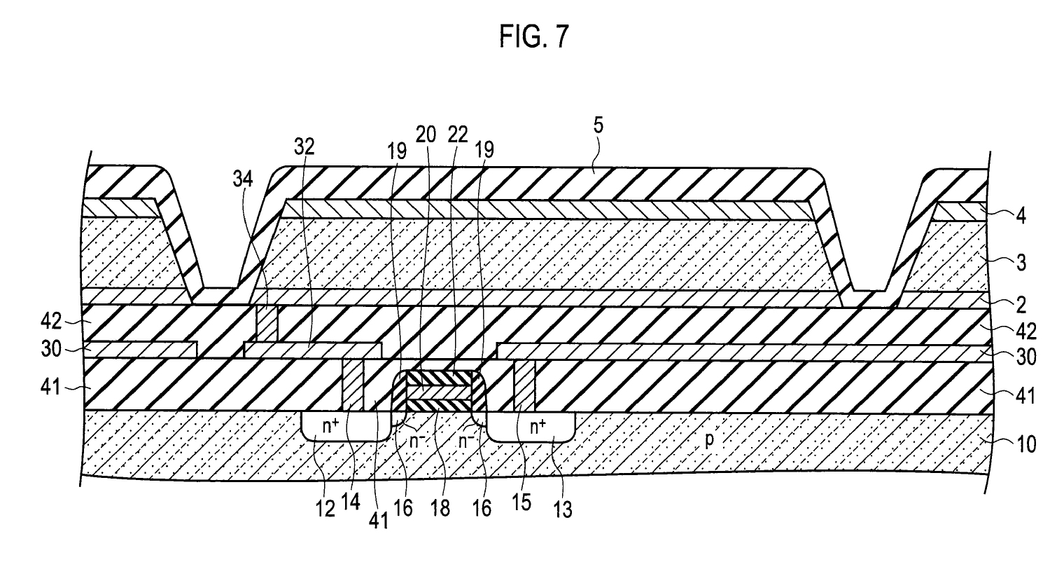

In detail, the upper electrode 4 may be formed by double layer structure. For example, an IrO₂ film is formed by the sputtering method contacting the ferroelectric film 3, and then an ITO film is similarly formed by the sputtering method on the IrO₂ film. The thick films of each layer are about several 10 nm to about 100 nm.
(f) Next, as shown in FIG. 5, the resist layer 7 is formed on the upper electrode 4, and is patterned according to photo lithography and an etching process. After demarcating the formation area of the ferroelectric capacitor by the photolithography technology and etching the upper electrode 4 selectively by the dry etching, the resist layer 7 is removed. As a dry etching gas series, halogen based gas, such as a chlorine series or a bromine series, or argon (Ar) based gas can be used, for example. Ar gas, Cl₂ gas, or HBr gas is applicable for the ITO, for example.
(g) Next, as shown in FIG. 5, the ferroelectric film 3 and the lower electrode 2 by applying the ITO of the upper electrode 4 as a mask are removed by dry etching. It is effective to switch the gas series of dry etching and perform the dry etching of each layer. As the dry etching gas series, halogen based gas, such as a chlorine series or a bromine series, or argon (Ar) based gas can be used, for example. Specifically, C₄F₈ gas, CF₄ gas, or Ar gas are applicable for PLZT, for example. C₄F₈ gas, CF₄ gas, Ar gas, or Cl₂ gas is applicable for Pt which forms the lower electrode 2.
(h) Next, as shown in FIG. 7, the dielectric multilayer 5 is formed all over the device surface. When forming the dielectric multilayer 5 with a silicon dioxide film and a silicon nitride film, the fabricating process and fabricating apparatus of the silicon semiconductor integrated circuit can be used. The dielectric multilayer 5 can be formed by PCVD (Plasma Chemical Vapor Deposition) method. The SiO₂ film can be preferably grown up in TEOS and O₂ atmosphere, and the Si₃N₄ film can be preferably grown up in SiH₄ and NH₃ atmosphere. Moreover, the dielectric multilayer 5 may be formed by the ion beam sputtering method.

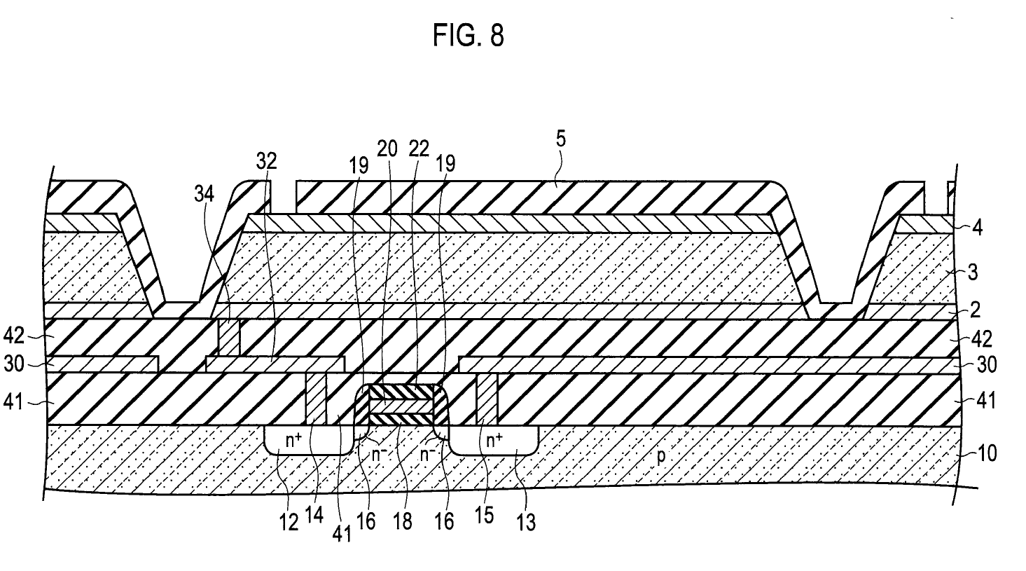

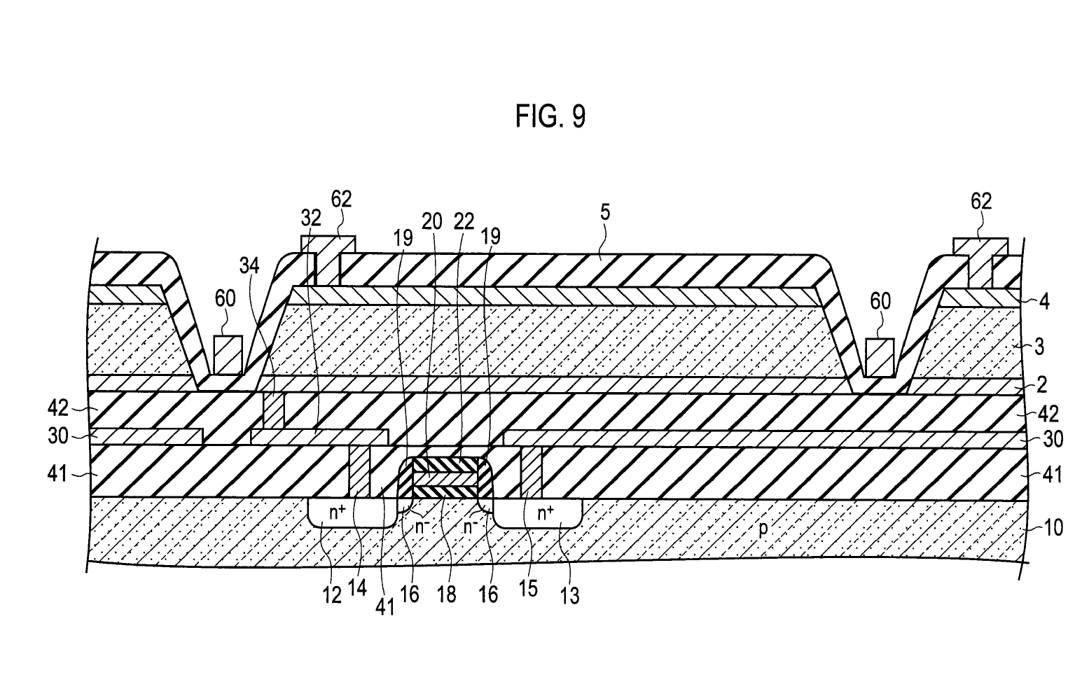

In addition, since the top surface of the ferroelectric film 3 has a tapered shape step, it may combine the process step for planarizing by embedding this tapered shape step with insulating films, such as TEOS.
(i) Next, as shown in FIG. 8, the dielectric multilayer 5 is patterned and the contact hole is formed for the upper electrode 4.
(j) Next, as shown in FIG. 9, the electrode wirings 62 and 60 are formed.

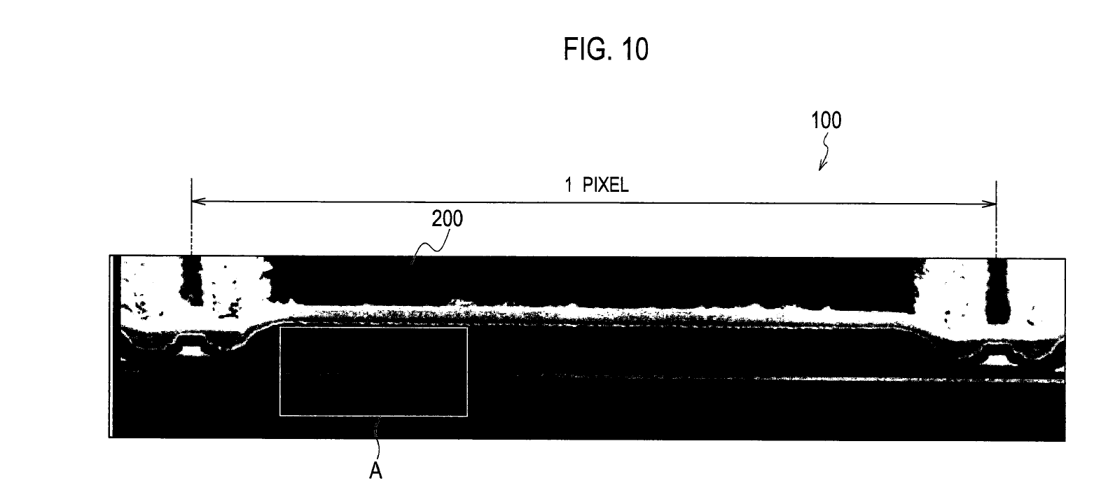

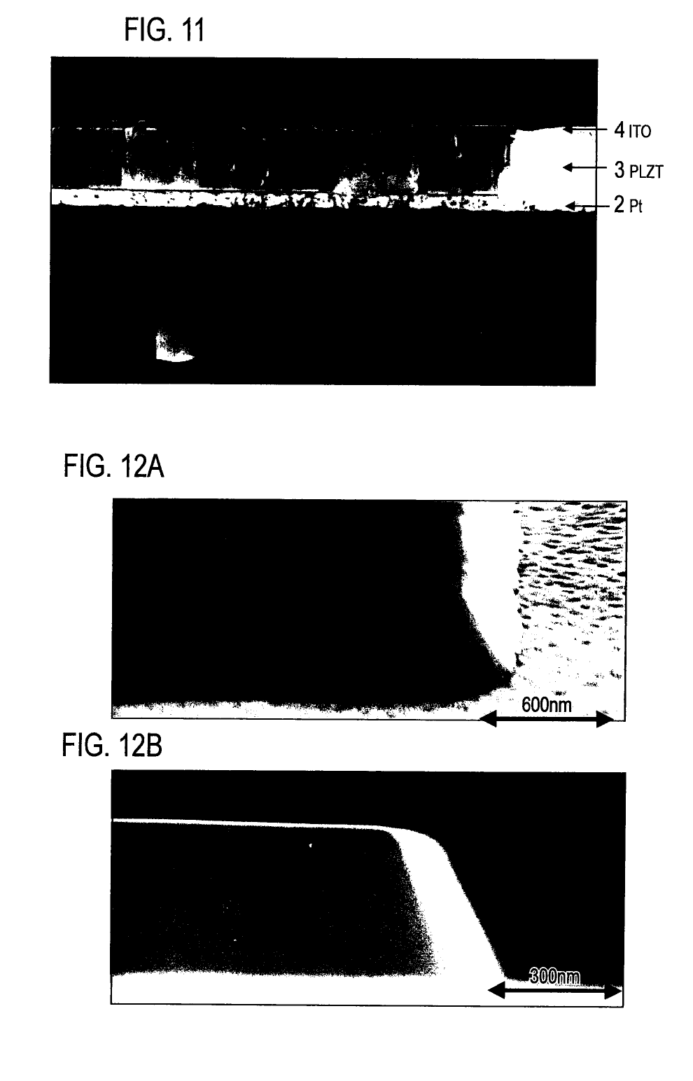

An SEM cross section photograph of one pixel part of the light modulation device according to the first embodiment formed by the above-mentioned fabrication method is expressed as shown in FIG. 10. Moreover, an expansion SEM photograph of a part of A of FIG. 10 is expressed as shown in FIG. 11. It proves that the structure shown in FIG. 10 and FIG. 11 corresponds with FIG. 1B. Moreover, in the fabrication method of the light modulation device according to the first embodiment, an SEM photograph which etched the PLZT using the ITO as a mask is expressed as shown in FIG. 12A. Moreover, a cross section SEM photograph corresponding to FIG. 12A is expressed as shown in FIG. 12B.

According to the present embodiment, the semiconductor device which uses the ITO used as the transparent electrode as the etching mask of the PLZT, performs the self-aligned formation, and has the easy fabrication method, and the fabrication method for the semiconductor device can be provided.

According to the present embodiment, the light modulation device which uses the ITO used as the transparent electrode as the etching mask of the PLZT, is able to etch by self-align, and has the easy fabrication method, and the fabrication method for the light modulation device can be provided.

### Other Embodiments

The present invention has been described by the first embodiment, as a disclosure including associated description and drawings to be construed as illustrative, not restrictive. With the disclosure, artisan might easily think up alternative embodiments, embodiment examples, or application techniques.

Such being the case, the present invention covers a variety of embodiments, whether described or not.

### INDUSTRIAL APPLICABILITY

The semiconductor device or the light modulation device of the present invention is applicable to wide fields, such as a display device, a switch for optical communications, a light modulator, a laser beam printer, a copying machine, a light modulator of a holographic memory, an optical operation device, an enciphering circuit, a nonvolatile memory, a piezoelectric device, a hybrid (embedded) LSI memory.

### REFERENCE SIGNS LIST

3: Ferroelectric film;
4: Upper electrode;
5: Dielectric multilayer;
6: Resonator;
7: Resist layer;
8: Control circuit;
10: Semiconductor substrate;
12, 13: Source region or drain region (S/D region);
14, 15: Plug electrode;
16: High resistance region;
18: Gate insulating film;
19: Sidewall insulating film;
20: Gate electrode;
22: Cap insulating film;
30, 32: M1 electrode;
34: VIA electrode;
41, 42: Interlayer insulation film;
52: First dielectric film;
54: Second dielectric film;
60, 62: Electrode wiring;
100: Semiconductor device or light modulation device;
200: Pixel;
201: Memory cell transistor (Q_{M});
202: Ferroelectric capacitor (C_{F});
BL, BL1, BL2, . . . : Bit line; and
WL, WL1, WL2, . . . : Word line.

1. A semiconductor device comprising:
a ferroelectric capacitor comprising a lower electrode, a ferroelectric film placed on the lower electrode, and an upper electrode placed on the ferroelectric film, wherein
the upper electrode includes a conducting film by which self-alignment patterning is performed to the ferroelectric film as an etching mask of the ferroelectric film.

2. The semiconductor device according to claim 1, wherein the ferroelectric film includes at least one kind of PLZT, PZT, BST, SBT, LiNbO₃, SBN, TiBaO₃, LSCO, KDP, KTN, a PMN-PT based ceramic film, or a PZN-PT based ceramic film.

3. The semiconductor device according to claim 1, wherein the conducting film is ITO of a transparent conductive film.

4. The semiconductor device according to claim 1, wherein the lower electrode includes at least one kind of Pt, Ir, iridium oxide, or SRO.

5. A light modulation device comprising:
a substrate; and
a ferroelectric capacitor which is placed on the substrate, and comprises a lower electrode, a ferroelectric film placed on the lower electrode, and an upper electrode placed on the ferroelectric film, wherein
the upper electrode includes a conducting film by which self-alignment patterning is performed to the ferroelectric film as an etching mask of the ferroelectric film, and
the ferroelectric capacitor is provided so as to laminate on the substrate, and the ferroelectric capacitor is functioned as a Fabry-Perot type resonator from which a refractive index of the ferroelectric film changes according to an electric field applied between the lower electrode and the upper electrode.

6. The light modulation device according to claim 5 further comprising:
a dielectric thin film stacked or laminated section placed on the upper electrode.

7. A fabrication method for a semiconductor device comprising:
forming a lower electrode;
forming a ferroelectric film on the lower electrode;
forming an upper electrode including a conducting film on the ferroelectric film;
patterning the conducting film; and
etching the ferroelectric film and the lower electrode by applying the patterned conducting film as a mask, wherein
self-alignment patterning of the conducting film is performed to the ferroelectric film as an etching mask of the ferroelectric film.

8. The fabrication method for a semiconductor device according to claim 7, wherein the ferroelectric film includes at least one kind of PLZT, PZT, BST, SBT, LiNbO₃, SBN, TiBaO₃, LSCO, KDP, KTN, a PMN-PT based ceramic film, or a PZN-PT based ceramic film.

9. The fabrication method for a semiconductor device according to claim 7, wherein the conducting film is formed by ITO of a transparent conductive film.

10. The fabrication method for a semiconductor device according to claim 7, wherein the lower electrode is formed by at least one kind of Pt, Ir, iridium oxide, or SRO.

11. The fabrication method for a semiconductor device according to claim 7, wherein the step of using the ITO as the conducting film and etching the ferroelectric film and the lower electrode by applying the conducting film as the mask is performed by switching dry etching gas series.

12. The fabrication method for a semiconductor device according to claim 7, wherein the step of using the PLZT as the ferroelectric film and etching the ferroelectric film applies C₄F₈ gas, CF₄ gas, or Ar gas, as dry etching gas series.

13. The fabrication method for a semiconductor device according to claim 7, wherein the step of using the Pt as the lower electrode and etching the lower electrode applies one of C₄F₈ gas, CF₄ gas, Ar gas, or Cl₂ gas, as dry etching gas series.

14. A fabrication method for a semiconductor device comprising:
forming a ferroelectric capacitor on a substrate; and
forming a control circuit for driving the ferroelectric capacitor on the substrate, and wherein
the step of forming the ferroelectric capacitor comprises:
forming a lower electrode;
forming a ferroelectric film on the lower electrode;
forming an upper electrode including a conducting film on the ferroelectric film;
patterning the conducting film;
etching the ferroelectric film and the lower electrode by applying the conducting film as a mask; and
forming a dielectric thin film stacked or laminated section on the upper electrode,
wherein
self-alignment patterning of the conducting film is performed to the ferroelectric film as an etching mask of the ferroelectric film.

15. The fabrication method for a semiconductor device according to claim 14, wherein the ferroelectric film includes at least one kind of PLZT, PZT, BST, SBT, LiNbO₃, SBN, TiBaO₃, LSCO, KDP, KTN, a PMN-PT based ceramic film, or a PZN-PT based ceramic film.

16. The fabrication method for a semiconductor device according to claim 14, wherein the conducting film is formed by ITO of a transparent conductive film.

17. The fabrication method for a semiconductor device according to claim 14, wherein the lower electrode is formed by at least one kind of Pt, Ir, iridium oxide, or SRO.

18. The fabrication method for a semiconductor device according to claim 14, wherein the step of using the ITO as the conducting film and etching the ferroelectric film and the lower electrode by applying the conducting film as the mask is performed by switching dry etching gas series.

19. The fabrication method for a semiconductor device according to claim 14, wherein the step of using the PLZT as the ferroelectric film and etching the ferroelectric film applies C₄F₈ gas, CF₄ gas, or Ar gas, as dry etching gas series.

20. The fabrication method for a semiconductor device according to claim 14, wherein the step of using the Pt as the lower electrode and etching the lower electrode applies one of C₄F₈ gas, CF₄ gas, Ar gas, or Cl₂ gas, as dry etching gas series.
